(19) United States
(12) Patent Application Publication
(10) Pub. No.: US 2011/0290306 A1
(43) Pub. Date: Dec. 1, 2011

(54) SOLAR ARRAY CONFIGURATIONS

(76) Inventor: Todd Roberts, Brick, NJ (US)

(21) Appl. No.: 13/094,027

(22) Filed: Apr. 26, 2011

Related U.S. Application Data
(60) Provisional application No. 61/327,930, filed on Apr. 26, 2010.

(51) Int. Cl. H01L 31/048

(52) U.S. Cl. 136/251

(57) ABSTRACT

Provided is a photovoltaic (PV) array that is capable of being mounted as a unit onto a support structure. Also provided is a solar panel laminate that can be plugged into an electrical connector of the adjacent laminate by pressing the electrical connectors together or installing them in close proximity to one another. Additionally, a PV array is provided that comprises an array framework comprising a plurality of crossmembers that are prefabricated to match with the frame of the solar panel laminates. Also provided is support structures for PV arrays, including support structures that comprise a ballast. Further provided is a PV electrical generating power plant, and a system and method for optimizing power output from a PV array.

### CROSS REFERENCE TO RELATED APPLICATIONS

The present application claims priority to and the benefit of U.S. Provisional Application Ser. No. 61/327,930 filed 26 Apr. 2010; which is incorporated herein by reference in its entirety.

### BACKGROUND

The present application generally relates to solar energy collection. More specifically, configurations of solar panels and arrays of solar panels are provided that facilitate construction and installation of solar power plants while achieving efficient energy conversion.

Photovoltaic (PV) arrays are generally constructed by combining a plurality of solar panel laminates (also known as solar panels or modules), one at a time, on a rigid grid-like framework forming part of a fixed or pivotal support structure. The laminates on the framework are electrically connected in parallel or in series, according to the power output requirements of the operator.

Under current practice, the mounting of the solar panel laminates in place is accomplished in a two part process whereby an extruded aluminum frame that wraps around the entire laminate is press fit or attached to the panel laminate at the factory, and then this frame is attached to a separate and additional mounting system in the field which is attached to the ground (or a building or structure that is in turn attached to the ground).

Historically, installed solar generating systems were quite small and rarely exceeded about 10 kW. Today, typical panel laminate designs have a rated capacity of approximately 200 W each or more, so a 10 kW system requires approximately 50 Panel Laminates to complete. However, interest in solar power generation has expanded exponentially during the past decade, and larger utility scale installations exceeding 15 MW in rated capacity are becoming more common. This trend toward larger scale projects is expected to continue and accelerate in the future. To complete a typical system with 15 MW of rated capacity in 2009, more than 75,000 panel laminates are required (and each would have to be individually handled and mounted in the field). A system that reduces the labor required to install such an array of laminates would be desirable. The present invention provides such a system, along with other systems that make installation and use of PV arrays simpler and more efficient.

### SUMMARY

Provided herewith are PV arrays, support structures, PV electrical generating power plants, and systems useful for efficient construction and use of PV systems.

In some embodiments, a PV array is provided. The PV array comprises an array framework and a plurality of electrically coupled solar panel laminates coupled to the array framework. In these embodiments, each solar panel laminate comprises a plurality of electrically coupled solar cells; a grounding means; an insulating cover and backing; and an electrical connector. The PV array of these embodiments is capable of being mounted as a unit onto a support structure to generate electricity when sunlight impinges on the mounted photovoltaic array.

Also provided is a solar panel laminate. The solar laminate comprises a plurality of electrically coupled solar cells; a grounding means; an insulating cover and backing; and an electrical connector. In these embodiments, the solar panel laminate can be electrically coupled to an adjacent laminate through an electrical connector that protrudes from the laminate or a frame circumscribing the laminate, such that the electrical connector of the laminate can be plugged into an electrical connector of the adjacent laminate by pressing the electrical connectors together or installing them in close proximity to one another.

Additionally, a photovoltaic PV array is provided that comprises an array framework and a plurality of electrically coupled solar panel laminates coupled to the array framework. Each solar panel laminate in the array comprises a plurality of electrically coupled solar cells; a grounding means; an insulating cover and backing; and an electrical connector. In these embodiments, each solar panel laminate further comprises a frame circumscribing the laminate, where the frame comprises a first axis and a second axis. The array framework comprises a plurality of crossmembers, where each crossmember is joined to the frame of more than one laminate. The crossmembers are prefabricated to match with the frame of the solar panel laminates, such that the laminates are coupled to the crossmembers in one predesigned, repeatable orientation with a predesigned, repeatable spacing between solar panel laminates.

Further, a support structure for a PV array is provided. The support structure comprises a substantially vertical first support member and a substantially vertical second support member, where each of the first support member and the second support member comprises an upper end and a lower end, the lower end coupled to a base and the base deposed on, attached to, or embedded into a ground, a flooring or a building element. The support structure further comprises a rotatable mount spanning the first vertical support member and the second vertical support member, where the rotatable mount is coupled to a first bearing located at the upper end of the first support member and a second bearing located at the upper end of the second support member. The rotatable mount is capable of coupling to a PV array or a plurality of solar panel laminates, and the PV array is coupled to the rotatable mount through a rectangular tube or block deposed on the rotatable mount.

A support structure for a PV array is also provided. The support structure comprises a substantially vertical first support member comprising a first upper end and a first lower end, the lower end coupled to a first base. In these embodiments, the base of the support member comprises a first ballast.

In additional embodiments, a PV electrical generating power plant is provided. The power plant comprises a plurality of any the above-described support structures and a PV array deposed on the rotatable mount of each support structure. In the power plant, the bases of the plurality of support structures are anchored, ballasted or embedded in an area where the PV array is exposed to sunlight.

Additionally provided is a system for optimizing power output from a PV array, where the PV array is mounted on a support structure and comprises at least one solar panel laminate. In these systems, the solar panel laminate comprises a plurality of electrically coupled solar cells; a grounding means; an insulating cover and backing; and an electrical connector, and the support structure comprises a substantially vertical first support member comprising a first upper end and a first lower end, the lower end coupled to a first base; and a means for rotating the PV around an axis, where the axis is substantially horizontal axis or at a selected angle of inclination to the horizon. The system comprises a means for measuring the power output of the PV array before and after rotating the PV array around the axis less than 5 degrees; a means for determining whether the power output of the PV array before or after rotating the PV array around the axis less than 5 degrees is greater; and a means for rotating the PV array to the position where the power output is greater.

Also provided is a method of optimizing power output from a photovoltaic (PV) array, where the PV array is mounted on a support structure and comprises at least one solar panel laminate. The solar panel laminate comprises a plurality of electrically coupled solar cells; a grounding means; an insulating cover and backing; an electrical connector; and a means for measuring power output from the array, and the support structure comprises a substantially vertical first support member comprising a first upper end and a first lower end, the lower end coupled to a first base; and a means for rotating the PV around an axis, wherein the axis is substantially horizontal axis or at a selected angle of inclination to the horizon. The method comprises measuring the power output of the PV array before and after rotating the PV array around the axis less than 5 degrees; determining whether the power output of the PV array before or after rotating the PV array around the axis less than 5 degrees is greater; and rotating the PV array to the position where the power output is greater.

### BRIEF DESCRIPTION OF THE DRAWINGS

FIG. 1 is a perspective view of a PV array in accordance with an illustrative embodiment.

FIG. 2 is a cutaway view of a PV array deposed on a support structure in accordance with an illustrative embodiment.

FIG. 3 is a perspective view of a PV array deposed on a support structure in accordance with an illustrative embodiment.

FIG. 4 is a side perspective view of a PV array deposed on a support structure in accordance with an illustrative embodiment.

FIG. 5 is a front perspective view of two PV arrays deposed on support structures in accordance with an illustrative embodiment.

FIG. 6 is a bottom perspective view of three PV arrays deposed on support structures in accordance with an illustrative embodiment.

FIG. 7 is a perspective view of a portion of a PV array deposed on a support structure in accordance with an illustrative embodiment.

FIG. 8 is a flow chart of a method in accordance with an illustrative embodiment.

### DETAILED DESCRIPTION

The terminology used herein is for describing particular embodiments only and is not intended to be limiting of the invention. As used herein, the singular forms “a”, “an” and “the” are intended to include the plural forms as well, unless the context clearly indicates otherwise. In addition, as referenced herein, a module is defined as hardware, software, and/or a combination thereof for performing a particular function. Software is defined as computer executable instructions including, but not limited to, object code, assembly code, and machine code. Hardware may include, but is not limited to, one or more processors/microprocessors, electronic circuitry, and other physical components. It will be further understood that the terms “comprise” and/or “comprising,” when used in this specification and/or the claims, specify the presence of stated features, integers, steps, operations, elements, and/or components, but do not preclude the presence or addition of one or more other features, integers, steps, operations, elements, components, and/or groups thereof.

Provided here are photovoltaic (PV) laminates, arrays, support structures and power plants that are standardized, easy to install, and allow installation where PV arrays have not previously been an option or an efficient option.

As used herein, a PV laminate, also called a solar panel or a solar module, is a grouping of solar cells that are connected together and laminated in a panel, with exposed electrical leads (+ and −). A common PV laminate configuration currently utilizes standard 6 inch solar cells, soldered together in 6 groups of 10, assembled and encapsulated between glass and a Tedlar backing with 2 sheets of ethylene vinyl alcohol (EVA) film using an industrial laminator, with bypass diodes between the 6 groups of 10 in a junction box with two leads (+ and −) emerging therefrom. Such typical PV laminates have a 200 W capacity or more. However, the PV laminates provided here are not narrowly limited to any particular configuration or electrical output, and could encompass any configuration known in the art.

As used herein, a PV array is a plurality of PV laminates joined together and deposed on a support structure. The PV laminates in an array are usually electrically coupled such that the array has one electrical output. A PV array can comprise any number of laminates, including 2, 3, 4, 5, 6, 7, 8, 9, 10, 11, 12, 13, 14, 15, 16 or more laminates.

As discussed in the BACKGROUND section above, current PV arrays are generally constructed by mounting solar panel laminates one at a time onto a support structure on site. Where many PV arrays are installed, such as at a 15 MW solar power plant, the labor costs of installing the laminates is significant. To address this problem, PV arrays are provided here where at least some of the laminates are already installed on a framework such that the framework can be mounted as a unit onto the support structure. This system provides significant savings in labor since the framework for each laminate does not have to be constructed on site and at least some of the laminates do not have to be individually mounted on the framework. Thus, in some embodiments, a PV array is provided. The PV array comprises an array framework and a plurality of electrically coupled solar panel laminates coupled to the array framework. In these embodiments, each solar panel laminate comprises a plurality of electrically coupled solar cells, a grounding means, an insulating cover and backing, and an electrical connector. The PV array of these embodiments are capable of being mounted as a unit onto a support structure to generate electricity when sunlight impinges on the mounted photovoltaic array.

While it is understood that in many cases a PV array with a full complement of laminates (e.g., 12 laminates) mounted onto the framework is so heavy that lifting such an array would require heavy equipment, the use of such equipment can be avoided by constructing the framework to support the full complement of laminates, while installing a minimum number of laminates (e.g., two, three, four or five), then mounting this unit onto the support structure. The remainder of the laminates can then be mounted onto the framework with the framework in place on the support structure. In some embodiments, the framework is standardized for a particular laminate, which facilitates installation of the laminates onto the framework.

In an alternative embodiment, sub-arrays are constructed comprising two or more laminates on a frame, where more than one sub-array is mounted on a support structure.

The array framework can be constructed of any suitable material, e.g., having sufficient strength to support the laminates. For example, the array framework can be made of plastic, wood or metal, e.g., aluminum or galvanized steel.

The loading strength of the laminates and the finished arrays must meet expected environmental demands, such as snow loading and loading from wind pressures. Typical loading requirements for the laminates are approximately 50 pounds per square foot. In various embodiments, the framework array is also capable of withstanding at least 60 pounds per square foot of wind load and gusts to 130 mph or more. The strength of the framework can be enhanced, and installation of the laminates onto the framework can be facilitated, by providing each solar panel laminate with a frame circumscribing the laminate, and by physically interconnecting the laminates, e.g., with connectors that couple the frames circumscribing adjacent laminates. This frame can also be made of any suitable material, including metal, wood or plastic. In some embodiments, the frame is extruded aluminum.

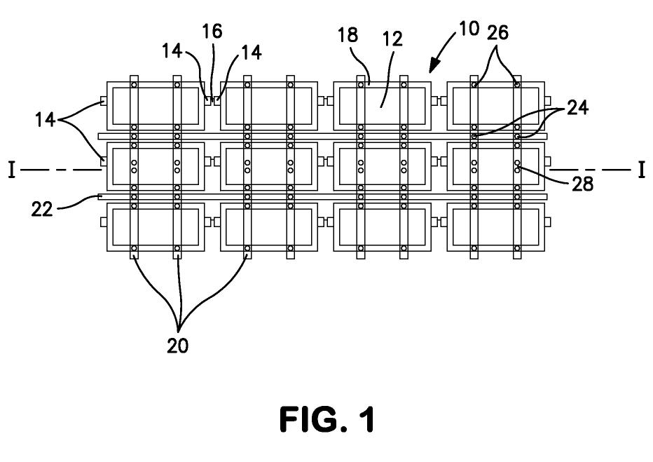

Matching specific frame designs to a standardized array interconnection can provide a measure of added loading strength. An exemplary design is provided in FIG. 1. A PV array 10 comprises twelve laminates 12, electrical connectors in a junction box 14 electrically coupled by electrical leads 16 from the junction box 14. Each laminate 12 is circumscribed by a frame 18. Two vertical (as viewed) crossmembers 20 are coupled to each laminate frame 18 along the wide frame dimension with fasteners 26 and, optionally, horizontal (as viewed) crossmembers 22 are coupled to the vertical crossmembers 20 with fasteners 24. In some embodiments, the crossmembers and laminate frames are standardized for a particular laminate, e.g., with predrilled holes for the fasteners, and presized crossmembers and frames, allowing for rapid construction of the arrays by mounting the laminates to the frames and the crossmembers in a standardized fashion. The fasteners for these arrays can be of any suitable type known in the art, including nuts and bolts, screws, welds or clamps. The array in FIG. 1 also includes predrilled holes 28 for fastening the array along the central long axis Ito a support structure. In some embodiments, the crossmembers and frames further comprise visual guides or notches to provide orienting cues or mating structures to ensure proper orientation of the crossmembers with the frames.

These designs can be used with solar panel laminates of any type of having any capacity of power generation, for example at least 100 W, at least 500 W, or at least 1000 W at STC(Pm). Additionally, these designs are useful for PV arrays of any capacity, for example PV arrays capable of generating at least 500 W, at least 2 kW, at least 5 kW, at least 10 kW, or at least 20 kW.

Interconnecting the multiple panel laminates requires interconnection of the power producing characteristics of the laminates and interconnection of the grounding characteristics of the system. The system grounding is needed to dissipate any (i) stray current leakages from the laminates that may occur over time (either as a result of natural aging, faulty construction or accidental damage) and (ii) any outside current running through the system (such as those arising from any accidental cross connection with the grid supplied power system or from lightning strikes). In some embodiments, the grounding means is the framework crossmembers. In these embodiments, the crossmembers are connected by grounding wires to ground. In other embodiments, the crossmembers do not serve as a ground. If an insulating material is used for the crossmembers, each of the individual Panel Laminate frames must be separately electrically interconnected to ground.

The solar cells for these arrays can be made from any suitable material known in the art, for example cadmium telluride, copper indium, selenide/sulfide or gallium arsenide, or silicon, including crystalline or amorphous silicon.

The solar panel laminates can have any configuration or be made using any materials or methods known in the art. In some embodiments, each solar panel laminate is covered with a transparent material, e.g., glass or plastic. The solar panel laminates can also comprise any number of solar cells, for example at least 10, 25, 50 or 100 solar cells. In some embodiments, the laminate comprises 60 solar cells (e.g., 6 rows of 10). Further, the PV array or sub-array can comprise any number of solar panel laminates, for example at least 2, at least 4, at least 8, or at least 12 solar panel laminates.

In some embodiments, the PV arrays are designed to be used as a shelter. Such PV arrays are configured such that rain and/or light cannot pass through to the area beneath the arrays.

In various embodiments, the electrical interconnection between panel laminates is through leads on junction boxes as are known in the art. In other embodiments, the electrical connector of each solar panel laminate protrudes from an edge of each laminate or a frame circumscribing each laminate, such that the electrical connector of each laminate can be plugged into the electrical connector of an adjacent laminate by pressing the electrical connectors together. In some of these embodiments, the connectors are situated such that the electrical connectors are pressed together by pressing the laminates together. Such a “plug and play” system expedites mounting and interconnecting the laminates onto the array framework, particularly where the array framework and the panel frames are precisely matched to only allow a single repeatable spacing and placement design.

Thus, in some embodiments, each solar panel laminate comprises an extruded aluminum frame circumscribing the laminate. In these embodiments, the array framework comprises two crossmembers attached to the frame of each laminate at least two points of interconnection along a first axis of each laminate, each solar panel laminate is capable of generating at least 200 W at STC(Pm), the solar cells are made from crystalline or amorphous silicon, each solar panel laminate is covered with glass, the insulating cover and backing comprises an EVA laminate, each solar panel laminate comprises at least 60 solar cells, and the PV array comprises 12 laminates.

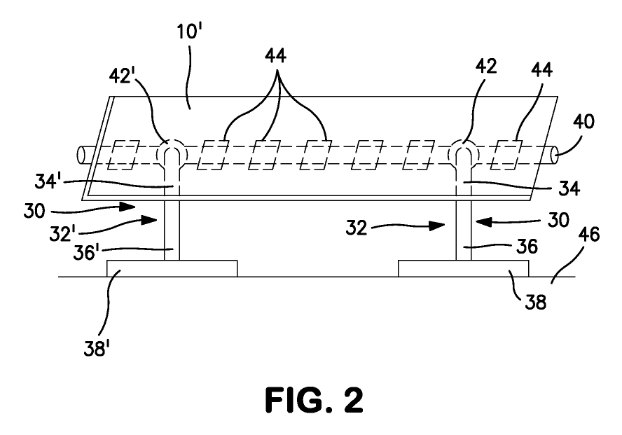

Also provided herewith are support structures for photovoltaic (PV) arrays. FIG. 2 provides an illustration of an exemplary embodiment. The support structure 30 comprises a substantially vertical first support member 32 and a substantially vertical second support member 32′, where each of the first support member 32 and the second support member 32′ comprises an upper end 34, 34′ and a lower end 36, 36′. The lower end 36, 36′ of each support member 32, 32′ is coupled to a base 38, 38′ with each base deposed on, attached to, or embedded into a ground 46, a flooring, a mobile platform, or a building element. The support structure 30 also comprises a rotatable mount 40 spanning the first vertical support member 32 and the second vertical support member 32′, the rotatable mount coupled to a first bearing 42 located at the upper end 34 of the first support member 32 and a second bearing 42′ located at the upper end 34′ of the second support member 32′. In these embodiments, the rotatable mount 40 is capable of coupling to a PV array or a plurality of solar panel laminates through a rectangular tube or block 44 deposed on the rotatable mount 40. In various aspects of these embodiments, several rectangular tubes or blocks 44 are deposed along the rotatable mount. The rectangular tubes or blocks 44 can be any length along the rotatable mount. In some embodiments, the rectangular tubes or blocks 44 are square.

The rectangular tube or block 44 can be deposed on the rotatable mount 40 in any manner suitable for supporting the PV array 10′. In some embodiments, the rectangular tube or block 44 comprises a wide dimension wider than the diameter of the rotatable mount, and is deposed on the rotatable mount 40 with the wide dimension across the rotatable mount 40. The rectangular tube or block 44 can be deposed on the top of the rotatable mount 40, e.g., using a weld or nuts and bolts. In other embodiments, the rectangular tube or block 44 completely surrounds the rotatable mount 40. Such rectangular tubes or blocks 44 can be installed in any manner, for example by drilling out the center of a block and inserting the rotatable mount prior to fixing the block in place by fastening or welding around the circumference of the rotatable mount. The rectangular tube or block 44 can cover the rotatable mount 40, or the top point of the rotatable mount 40 and the rectangular tube or block 44 can be at the same level, providing a continuous flat surface on the top. In various embodiments, particularly where the PV array utilized is the PV array described above, multiple rectangular tubes or blocks 44 are deposed at each point of connection to the crossmembers 28 of the PV array 10. In some of these embodiments, the crossmembers 28 and rectangular tubes or blocks 44 are deposed at approximately every 2.7 feet. In other embodiments, the rectangular tubes or blocks 44 are paired such that an even number of rectangular tubes or blocks 44 are along the rotatable mount 40.

The support structure can be deposed on or into any surface suitable for bearing the support structure and PV array, including but not limited to a roof, a floor, a mobile platform such as a flatbed semi trailer, or the ground. Where the support structure is on the ground, it can be deposed on or embedded into the ground. When embedded into the ground, the base must be embedded deep enough (e.g., below the frost line), with sufficient anchorage (e.g., in holes that are filled with concrete), such that the support structure with PV array is stable under the ambient environmental conditions. If the arrays are to be mounted on a building or other structure, the vertical support members are connected to the structure in accordance with the loading requirements and specifications for the applicable building conditions, using flanges or other appropriate load distributing connection materials. In various embodiments, the base should support the structure under 60 pounds per square ft of wind loading and wind gusts to 130 mph or more.

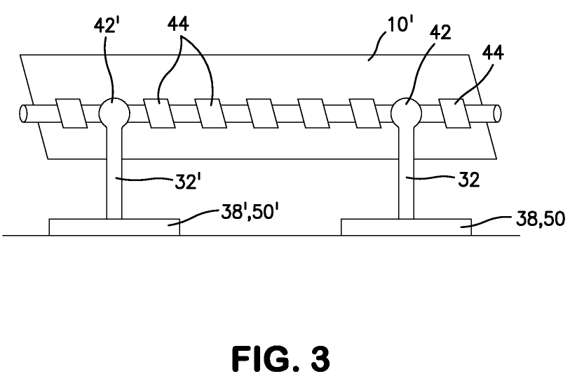

In some embodiments, the base of each support member comprises a ballast. As used herein, a ballast is a heavy structure deposed at the base of the support structure that provides support for the structure and PV array installed thereon. An exemplary ballasted support structure with PV array is illustrated in FIG. 3. The base 38, 38′ of each support member 32, 32′ comprises a ballast 50, 50′. In various embodiments, the ballast 50, 50′ does not penetrate the ground, or does not penetrate the ground by more than 10 inches.

A ballasted support structure with a PV array is particularly useful where providing a base that penetrates the ground is impractical or impossible, for example where the support structure is placed on an impenetrable surface, for example on a ground where an impenetrable bedrock is present, or on a capped landfill, where penetrating the clay cap of the landfill is undesirable or prohibited. The ballasted anchoring system can also be used in building or structure-mounted systems where the PV arrays sit on top of the building or structure on ballasted supports that are not permanently attached to the building or structure.

The ballasted support structure can also be mounted onto a mobile platform such as a flat bed semi trailer. Such a mobile solar system is particularly useful to provide power to remote locations, in emergency situations where there is a power failure, or for military uses. In alternative embodiments, the support structure can be mounted onto the mobile platform by bolting or otherwise securing at least one of the support members to the platform, with or without a ballast. In these embodiments, the support structure can be mounted onto the mobile platform before or after the PV array is deposed on the rotatable mount.

The ballast is preferably heavy enough and wide enough to provide sufficient support to maintain the stability of the rest of the support structure with PV array under 60 pounds per square ft of wind loading and wind gusts to 130 mph or more. In various embodiments, to provide sufficient support, the ballast covers an area of greater than 4 square feet.

The ballast can be made of any heavy material, for example a material comprising cement, e.g., concrete, or metal.

The support structures provided herein can be part of a shelter, e.g., for shade or protection from the rain for people or animals, or as a carport for vehicles. In these embodiments, rain and/or light cannot pass through the PV array, or the support structure is integrated with a roof providing that protection. In various embodiments, the support structure further comprises walls to form an enclosed structure, or is integrated with a building providing walls.

Where the support structure is part of a shelter, the PV array is preferably high enough such that people or vehicles can easily seek shelter underneath the PV array. As such, in some embodiments, the upper end of each support member is elevated at least 6 feet, at least 10 feet, or at least 16 ft. above the ground, flooring or building element.

The support structures provided herein can support any PV array known in the art. In some embodiments, the PV array deposed thereon is one of the PV arrays described above.

The rotatable mount 40 can have any design suitable for coupling to a bearing and capable of supporting the rectangular tube or block(s) 44 that couple(s) to the PV array or plurality of solar panel laminates. In some embodiments, the rotatable mount 40 is a substantially cylindrical tube, e.g., a galvanized steel pipe or an aluminum pipe. The rotatable mount can be any appropriate length for the PV array deposed thereon. In some embodiments, the rotatable mount is about 25 ft. long.

Any bearing known in the art can be used to support the rotatable mount 40 on each vertical support member 32, 32′. A particularly suitable bearing is a pillow block bearing 42, 42′.

The rotatable mount 40 can be further supported by a substantially vertical third support member. In various embodiments, the third support member comprises an upper end and a lower end, the lower end coupled to a base and the base deposed on, attached to, or embedded into the ground, the flooring or the building element. In these embodiments, the rotatable mount is coupled to a third bearing located at the upper end of the third support member.

In other embodiments, the support structure comprises a third vertical support member and a second rotatable mount spanning the second vertical support member and the third vertical support member, the second rotatable mount coupled to the second bearing and a third bearing, the third bearing located at the upper end of the third support member. Thus, in these embodiments, two rotatable mounts and PV arrays are supported on three vertical support members. Further, there can similarly be a sharing of additional vertical support members between rotatable mounts, such that three rotatable mounts can be supported on four vertical support members, four rotatable mounts can be supported on five vertical support members, etc.

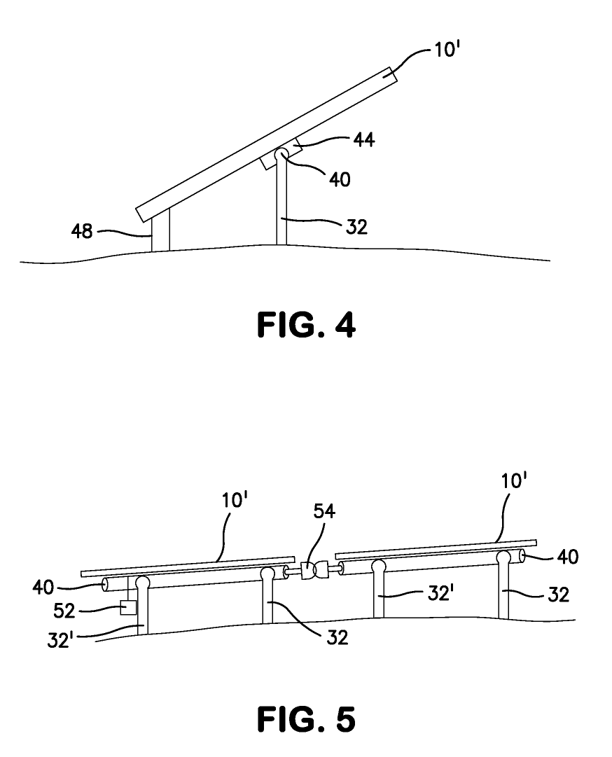

In some embodiments, the support structure is a fixed system, i.e., the PV array does not move during the day to track the daily movement of the sun. In these embodiments, the PV array is either horizontal to the ground or is directed toward the south in the northern hemisphere or the north in the southern hemisphere. Such a system is shown in FIG. 4, showing the fixed system from the end-on view of the rotatable mount 40. A rectangular tube or block 44 is also shown. The PV array 10′ in these embodiments is pointed toward the south in the northern hemisphere and the north in the southern hemisphere (to the left in FIG. 4). These fixed systems can optionally comprise one or several anchoring supports 48 that support the PV array at the selected angle of inclination.

In some embodiments, the fixed system is locked in place permanently at a fixed angle of inclination. In other embodiments, the fixed system is capable of periodic rotation to more closely match the seasonal angle of inclination of the sun in the noon sky. If fixed in place permanently, the system can have multiple attachment points to the ground (or the building or structure to which the system is connected). If adjusting periodically, the system can be situated such that one end of the horizontal rotatable mount can be raised or lowered to properly tilt the PV array to most directly face the sun to the south in the northern hemisphere or to the north in the southern hemisphere.

In solar energy collection systems, tracking the sun can lead to a significant increase in annual radiation falling on the tracked surface, thus an increase in efficiency and total power production, relative to a fixed structure. Thus, in various embodiments, the rotatable mount can be rotated in relation to a first axis along the rotatable mount, where the axis is substantially horizontal axis or at a selected angle of inclination to the horizon. In these embodiments, the first axis is directed substantially north-south, so the PV array can follow the sun throughout the day, i.e., to face east in the morning and west in the afternoon.

In some of these embodiments, the rotatable mount can be further adjusted along a second axis substantially perpendicular to the first axis (a two-axis system). Such an adjustment can be achieved by raising or lowering the upper end of at least one of the first support member or the second support member with respect to the ground, the flooring or the building element to adjust the rotatable mount along the second horizontal axis. This adjustment is employed to direct the PV array to follow the sun in its seasonal movement in relation to the southern horizon in the northern hemisphere and the northern horizon in the southern hemisphere. The two-axis tracking system allows the PV modules to face directly toward the sun regardless of the daily movement of the sun and the seasonal variation in the path of that movement. However, the structure for a two-axis system is more complex, costly, and prone to breakdown than a single-axis tracking solar energy collection structure.

An alternative design to the two axis system is where the rotatable mount is fixed at a selected angle of inclination to the horizon (a single-axis system). A single-axis tracking solar energy collection structure represents a reasonable compromise between the fixed structure and the two-axis structure. That is, a single-axis tracking structure achieves the benefit of an increase in efficiency over a fixed structure without the undesirable complexity and cost of a two-axis tracking structure.

A single-axis tracking structure moves the PV array around a single axis, and therefore approximates tracking of the actual position of the sun at any time. In some embodiments, a drive mechanism gradually rotates the PV array throughout the day from an east-facing direction in the morning to a west-facing direction in the afternoon. The PV array is brought back to the east-facing orientation for the next day. A single-axis tracking structure may rotate around an axis that is either horizontal or tilted on an angle relative to horizontal that corresponds to the latitude of the location. Tilted single-axis tracking structures generally achieve a performance that is improved relative to horizontal single-axis tracking structures because they place the array of PV modules on average closer to perpendicular relative to the path of the sun. However, the improved performance of the horizontal single-axis systems is at least partially offset by the increased distance that tilted single-axis tracking structures must be from each other than horizontal systems, since shadows from adjacent structures can otherwise reduce the performance of the tilted systems. If the natural slope of the site is inclined, as on a hill, then this shading concern can be minimized or alleviated.

Single-axis and two-axis systems further generally include one or more drive mechanisms that rotate the support structure around the one or more axes, either continuously or on an intermittent basis, to aim the PV modules toward the sun as the sun moves across the sky during the day and as the sun path moves in the sky during the year. Numerous such drive mechanisms are known in the art. An example of a useful drive means is a reversible electric motor mechanically coupled to a hydraulic arm or gears, which are mechanically coupled to the rotatable mount.

The drive means is configured to rotate the PV array deposed on the rotatable mount by any selected amount, taking spacing requirements and power production under consideration. In some embodiments, the PV array can rotate at least 30 degrees in each direction of rotation from a vertical plane formed by the first support member and the second support member. In other embodiments, the PV array can rotate at least 35 degrees in each direction; in additional embodiments, the PV array can rotate at least 60 degrees in each direction.

In some embodiments, the support structure also comprises a means for adjusting the aspect of the PV array on the rotatable mount or on at least one of the vertical supports. Such adjustment is useful when the system is installed, to compensate for settling after the system is installed, or to seasonally change the tilt of a one axis or fixed system to more closely point the array toward the sun. Any means known in the art for adjusting the aspect of the PV array can be utilized here. One exemplary means is a mounting surface for the bearings that accepts shims to provide for vertical adjustment. Optionally, this mounting surface also provides for horizontal adjustment of the bearings. Other such means for adjusting the aspect of the PV array is integral with at least one of the vertical supports or the bearings. Such means include the provision of an outer sleeve that terminates at the base, and an inner sleeve that is attached to the bearing end of the support attached to the horizontal rotating mount. The inner sleeve be adjusted by, e.g., using screws, pins or shims to modify the height of the support.

Also provided herein is a PV electrical generating power plant. The power plant comprises a plurality of any of the above-described support structures and a PV array deposed on the rotatable mount of each support structure. In the power plant, the bases of the plurality of support structures are anchored or embedded in an area where the PV array is exposed to sunlight. In some of these embodiments, the PV array is any of the above described PV arrays. In various other embodiments, the PV arrays are inclined to the south if the PV power plant is in the northern hemisphere, or inclined to the north if the PV power plant is in the southern hemisphere. In various embodiments, the PV arrays are movable such that they can face east in the morning and west in the afternoon.

In additional embodiments, at least some of the support structures comprise a drive means for rotating the rotatable mount around a horizontal axis. In some of these embodiments, each support structure comprises a drive means. In alternative embodiments, the rotatable mount of each support structure is joined to a rotatable mount on an adjacent support structure, such that engaging the drive means on a first support structure imparts rotational force on the rotatable mount on the first support structure as well as on a rotatable mount on an adjacent support structure to which the rotatable mount on the first support structure is joined. An example of a useful drive means is a reversible electric motor mechanically coupled to a hydraulic arm or gears, which are mechanically coupled to the rotatable mount.

In some embodiments, each rotatable mount comprises a first end and a second end along a lengthwise rotational axis of the mount, each support structure is adjacent to another support structure along the lengthwise rotational axis of the rotatable mounts of each support structure, and the ends of the rotatable mounts of the adjacent support structures nearest to each other are joined such that engaging the drive means on one of the support structures imparts rotational force on the joined rotatable mount that is adjacent along the lengthwise rotational axis of the mount. Where the rotatable mounts are well-aligned such that adjustments between ends is unnecessary, the horizontal rotatable mounts can be coupled end to end through the use of fixed flanges. Alternatively, an inner sleeve connecting two end to end horizontal rotatable mounts could be fixed in place by using pins or bolts through the members and the inner sleeve to fix them in place in an interconnected fashion. Where small compensating adjustments are needed or advisable, the inner sleeve design just described could be fitted with a universal joint assembly that would break the sleeve into two interconnected parts that could rotate on an adjusted basis within the design specifications of the universal joint assembly. An example of those embodiments are illustrated in FIG. 5. The end to end horizontal rotatable mounts 40 having PV arrays 10′ deposed thereon are joined end to end by a universal joint 54, such that engaging the electric motor 52 rotates both horizontal rotatable mounts 40.

If the rotatable mounts along the lengthwise rotational axis are not in substantially the same plane along the lengthwise rotational axis and the ends of the rotatable mounts of the adjacent support structures nearest to each other along the lengthwise rotational axis are joined with gears, a chain and sprocket, and/or cables.

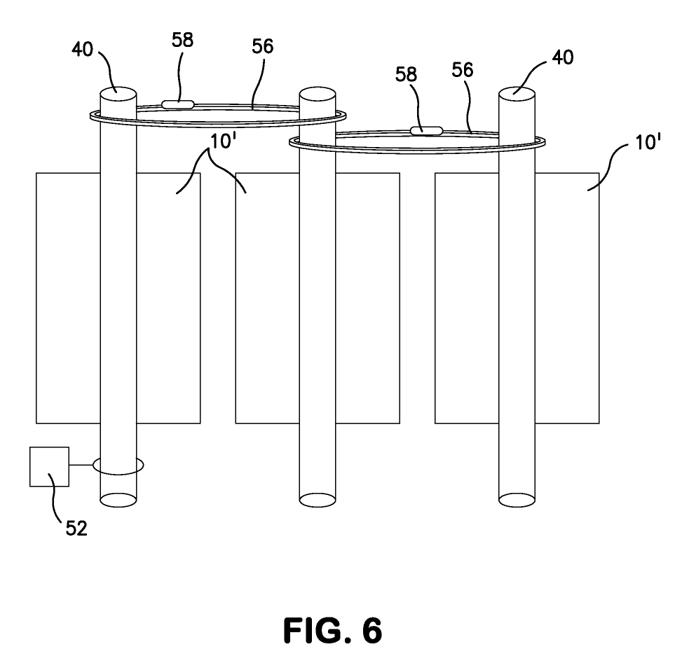

In other embodiments, each support structure is adjacent to another support structure such that the rotatable mounts of each support structure are substantially parallel to each other, and the rotatable mount of each support structure is joined to a parallel rotatable mount on an adjacent support structure such that engaging the drive means on one of the support structures imparts rotational force on the parallel joined rotatable mount. The parallel-adjacent rotatable mounts can be interconnected by any means, e.g., gears, a chain and sprocket, and/or cables. Alternatively, the parallel rotatable mounts are joined by counterwrapped wire cable pairs, as in FIG. 6, where the rotatable mounts 40 having PV arrays 10′ deposed thereon are joined to adjacent mounts by counterwrapped wire cable pairs 56 such that engaging the electric motor 52 rotates all three horizontal rotatable mounts 40. The counterwrapped wire cable pairs can further comprise adjustment turnbuckles 58 to adjust the tension on the wire cables. The adjustment turnbuckles 58 can also provide fine tuning adjustment to the positioning of the arrays 10′ relative to one another.

The PV power plants provided herewith can comprise any number of support structures, including at least 25, at least 100, or at least 500 support structures. Additionally, the power plants can generate any amount of electricity, for example at least 1 MW of electricity.

Single-axis and two-axis support structures are often somewhat misaligned such that the PV array is pointed slightly different from the expected direction toward the sun. Additionally, in some cases there are buildings or other obstructions at a site that can introduce shading on some or many of the panel laminates. Further, the panel laminates themselves can introduce shading to adjacent panel laminates in certain orientations, which may be dependent on time of day or year and the associated angle at which the solar irradiation from the sun hits the panel laminates. Provided here is a system and method for optimizing power output from a PV array by measuring the power output before and after moving the PV array, and then adjusting the PV array to a position where the power output is the highest. Thus, in some embodiments, a system is provided comprising a PV array is mounted on a support structure with at least one solar panel laminate deposed thereon. In this systems, the solar panel laminate comprises a plurality of electrically coupled solar cells, a grounding means, an insulating cover and backing, and an electrical connector, and the support structure comprises a substantially vertical first support member comprising a first upper end and a first lower end, the lower end coupled to a first base, and a means for rotating the PV around an axis. Here, the axis is a substantially horizontal axis or at a selected angle of inclination to the horizon. The system comprises (a) a means for measuring the power output of the PV array before and after rotating the PV array around the axis a small amount, e.g., less than 5 degrees (for example 1, 2, 3 or 4 degrees), preferably in both directions; (b) a means for determining whether the power output of the PV array before or after rotating the PV array around the axis is greater; and (c) a means for rotating the PV array to the position where the power output is greater. For these systems, the PV array and support structure can be any known in the art, including any of those described above.

In some embodiments, the means for determining whether the power output of the PV array before or after rotating the PV array around the axis less than 5 degrees is greater, and the means for rotating the PV array to a position where the power output is greater, is controlled by a computer chipset functionally linked to a drive mechanism capable of rotating the PV array around the axis. The computer chipset can be combined with a chipset that moves the PV array to face the sun during daylight hours. In some embodiments, the computer chipset comprises a clock function, a default position function tied to the clock function, and an algorithm tied to the clock function, where the algorithm tests the power output of the PV array at a base position and after rotating the PV array around the axis less than 5 degrees in a forward and reverse direction from the base position. The algorithm can be run as often as practical, for example at least once per hour during daylight hours, at least each 15 minutes during daylight hours, or once in the morning, once in the afternoon and once within an hour of noon. In some embodiments, the computer chipset stores the results from each run and anticipates the optimal position for subsequent runs using the prior results.

The system can comprise any number of other functions, for example a light sensor and an algorithm directing the drive mechanism to rotate the PV array to a stow position if the light sensor detects ambient light below a minimum value (e.g., at night or under a heavy cloud cover). The system can also comprise a wind sensor (anemometer) and an algorithm directing the drive mechanism to rotate the PV array to a horizontal position if the wind sensor detects windspeed exceeding a threshold value.

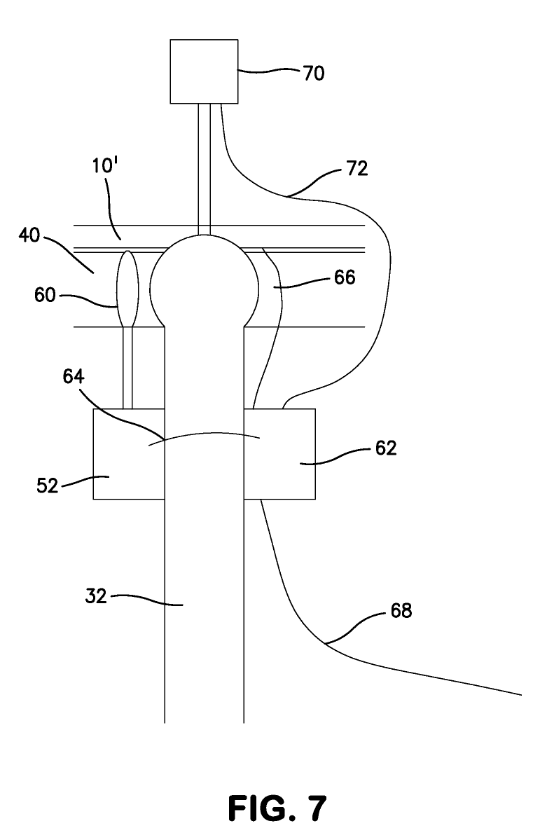

In some embodiments, the system is in a contained, weatherproof unit. In some of these embodiments, the unit is mounted near the drive mechanism. FIG. 7 is an illustration of one nonlimiting embodiment of this system. In this embodiment, a control box 62 has a computer chipset that controls the movement of the array 10′ through a wire connection 64 to an electric motor 52. Both the control box 62 and electric motor 52 are mounted on a vertical support member 32. The electric motor 52 is coupled to a rotatable mount 40 through a movement mechanism 60. The movement mechanism 60 can be any such mechanism known in the art. The control box 62 is also coupled to a first output wire 66, through which the electrical output from the array 10′ is directed. The computer chipset in the control box 62 measures the electrical output from the first output wire 66, which continues out of the system through a second output wire 68. The embodiment illustrated in FIG. 7 also includes an anemometer 70 coupled to the control box 62 through an anemometer wire 72.

Also provided is a method of optimizing power output from a photovoltaic (PV) array, where the PV array is mounted on a support structure and comprises at least one solar panel laminate. The solar panel laminate comprises a plurality of electrically coupled solar cells, a grounding means, an insulating cover and backing, an electrical connector, and a means for measuring power output from the array, and the support structure comprises a substantially vertical first support member comprising a first upper end and a first lower end, the lower end coupled to a first base, and a means for rotating the PV around an axis. The axis in these embodiments is a substantially horizontal axis or at a selected angle of inclination to the horizon. The method comprises (a) measuring the power output of the PV array before and after rotating the PV array around the axis less than 5 degrees (e.g., 1, 2, 3 or 4 degrees); (b) determining whether the power output of the PV array before or after rotating the PV array around the axis less than 5 degrees is greater; and (c) rotating the PV array to the position where the power output is greater. In some embodiments, the PV array is any of the PV arrays described above. In other embodiments, the support structure is any of the support structures described above. In additional embodiments, the method is performed using any of the systems described immediately above.

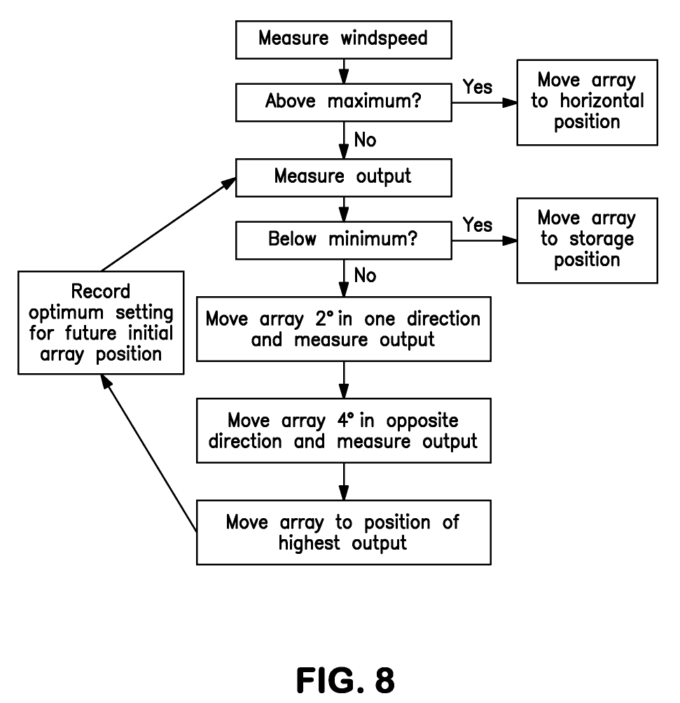

FIG. 8 is a flowchart showing the steps of one nonlimiting embodiment of these methods, using the system illustrated in FIG. 7. In this embodiment, the windspeed is first measured by the anemometer and the data is sent to a control box 62. The computer chipset in the control box 62 determines if the measured windspeed is above a maximum threshold. If the windspeed is above the threshold, the chipset directs the electric motor 52 to move the PV array 10′ to a horizontal position to minimize the effect of the wind. If the windspeed is below the threshold, the computer chipset in the control box 62 measures the output of the array 10′ coming from the first output wire 66. The computer chipset in the control box 62 then determines whether the output is below a minimum threshold, representing a level where the electrical output of the array is such that only insignificant amounts of electricity are being produced, as might occur during a heavy cloud cover or fog. If the output is below the minimum, the array is moved to a storage position. If the output is above the minimum threshold, the computer chipset in the control box 62 moves the PV array a small amount, e.g., 2°, in one direction, to a first moved position, and measures the electrical output, then moves the PV array a small amount e.g. 2° from the original position in the opposite direction (i.e., 4° from the first moved position) and measures the electrical output in that second moved position. The computer chipset then determines which of the three positions (the original position, the first moved position or the second moved position) has the highest output, then directs the electric motor 52 to move the array into that position. In some embodiments, the optimum setting, i.e., the position with the highest electrical output, is recorded and utilized in the determination of future initial array positions.

Computer program instructions for executing the disclosed embodiments may be stored in a computer-readable medium that can direct a computer or other programmable data processing apparatus to function in a particular manner, such that the instructions stored in the computer-readable medium produce instruction means which implement the function/act specified in the flowchart. The computer program instructions may also be loaded onto a data processing apparatus to cause a series of operational steps to be performed on the data processing system to produce a computer implemented process such that the instructions which execute on the data processing system provide processes for implementing the functions/acts specified in the flowchart and/or block diagram block or blocks.

Embodiments involving computer software and hardware, including chipsets, generally execute algorithms which implement method embodiments. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared and otherwise manipulated. It has proven convenient at times, principally for reasons of common usage, to refer to these signals as bits, values, elements, symbols, characters, terms, numbers or the like. It should be borne in mind, however, that all of these and similar terms are to be associated with the appropriate physical quantities and are merely convenient labels applied to these quantities. Unless specifically stated otherwise, it will be appreciated that throughout the present disclosure, use of terms such as “determining,” “directing” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Various embodiments may be implemented with the aid of computer-implemented processes or methods (a.k.a. programs or routines) that may be rendered in any computer language including, without limitation, C#, C/C++, Fortran, COBOL, PASCAL, assembly language, markup languages (e.g., HTML, SGML, XML, VoXML), and the like, as well as object-oriented environments such as the Common Object Request Broker Architecture (CORBA), Java™ and the like. In general, however, all of the aforementioned terms as used herein are meant to encompass any series of logical steps performed in a sequence to accomplish a given purpose.

Embodiments may be implemented with apparatus to perform the operations described herein. This apparatus may be specially constructed for the required purposes, or may comprise a general-purpose computer, selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, and each coupled to a computer system bus.

One of ordinary skill in the art will immediately appreciate that the teachings of the present disclosure may be practiced with computer system configurations other than those described above, including hand-held devices, multiprocessor systems, microprocessor-based or programmable consumer electronics, DSP devices, network PCs, minicomputers, mainframe computers, and the like, as well as in distributed computing environments where tasks are performed by remote processing devices that are linked through a communications network.

Other embodiments within the scope of the claims herein will be apparent to one skilled in the art from consideration of the specification or practice of the invention as disclosed herein. It is intended that the specification be considered exemplary only, with the scope and spirit of the invention being indicated by the claims.

### REFERENCES

U.S. Pat. No. 3,977,773.
U.S. Pat. No. 4,000,734.
U.S. Pat. No. 4,103,672.
U.S. Pat. No. 4,108,154.
U.S. Pat. No. 4,138,994.
U.S. Pat. No. 4,245,895.
U.S. Pat. No. 4,159,710.
U.S. Pat. No. 4,173,213.
U.S. Pat. No. 4,184,482.
U.S. Pat. No. 4,187,123.
U.S. Pat. No. 4,316,448.
U.S. Pat. No. 4,771,764.
U.S. Pat. No. 4,832,001.
U.S. Pat. No. 4,966,631.
U.S. Pat. No. 4,995,377.
U.S. Pat. No. 5,022,929.
U.S. Pat. No. 5,143,556.
U.S. Pat. No. 5,228,924.
U.S. Pat. No. 5,253,637.
U.S. Pat. No. 5,325,844.
U.S. Pat. No. 5,542,409.
U.S. Pat. No. 6,058,930.
U.S. Pat. No. 6,089,224.
U.S. Pat. No. 6,294,725.
U.S. Pat. No. 6,552,257.
U.S. Pat. No. 6,559,371.
U.S. Pat. No. 6,563,040.
U.S. Pat. No. 6,722,357.
U.S. Pat. No. 6,960,717.
U.S. Pat. No. 7,252,083.
U.S. Pat. No. 7,357,132.
U.S. Pat. No. 7,513,250.
U.S. Pat. No. 7,531,741.
U.S. Pat. No. 7,554,030.
U.S. Pat. No. 7,557,292.
U.S. Pat. No. 7,574,842.
U.S. Pat. No. 7,622,666.
U.S. Pat. No. 7,647,924.
U.S. Design Pat. No. 586,737.
U.S. Design Pat. No. 595,645.
U.S. Design Pat. No. 605,585.
U.S. Design Pat. No. 610,536.
Japanese Patent No. 58118021.

In view of the above, it will be seen that the several advantages of the invention are achieved and other advantages attained.

As various changes could be made in the above methods and compositions without departing from the scope of the invention, it is intended that all matter contained in the above description and shown in the accompanying drawings shall be interpreted as illustrative and not in a limiting sense.

All references cited in this specification are hereby incorporated by reference. The discussion of the references herein is intended merely to summarize the assertions made by the authors and no admission is made that any reference constitutes prior art. Applicants reserve the right to challenge the accuracy and pertinence of the cited references.

1. A photovoltaic (PV) array, comprising:
an array framework; and
a plurality of electrically coupled solar panel laminates coupled to the array framework, each solar panel laminate comprising:
a plurality of electrically coupled solar cells;
a grounding means;
an insulating cover and backing; and
an electrical connector
wherein the PV array is capable of being mounted as a unit onto a support structure to generate electricity when sunlight impinges on the mounted photovoltaic array.

2. The PV array of claim 1, wherein the array framework is metal.

3. The PV array of claim 1, wherein each solar panel laminate further comprises a frame circumscribing the laminate, the frame comprising a first axis and a second axis.

4. The PV array of claim 3, wherein the frame gives the solar panel laminate a design strength of at least 50 pounds per square foot.

5. The PV array of claim 3, wherein the frame is extruded aluminum.

6. The PV array of claim 3, wherein the array framework comprises a plurality of crossmembers, wherein each crossmember is joined to the frame of a plurality of laminates.

7. The PV array of claim 6, wherein the crossmembers are prefabricated to match with the frame of the solar panel laminates, such that the laminates are coupled to the crossmembers in one predesigned, repeatable orientation with a predesigned, repeatable spacing between solar panel laminates.

8. The PV array of claim 7, wherein the crossmembers are prefabricated with predrilled holes in the crossmembers and the frames of the solar panel laminates, such that the laminates are coupled by aligning the predrilled holes and joining the crossmembers and the frames with a fastener.

9. The PV array of claim 8, wherein the fastener is a clamp, a weld, a screw, or a bolt.

10. The PV array of claim 6, wherein the crossmembers and frames further comprise visual guides or notches to provide orienting cues or mating structures to ensure proper orientation of the crossmembers with the frames.

11. The PV array of claim 6, comprising two crossmembers coupled to the frame of each laminate at no less than two points of interconnection along the first axis of each laminate.

12. The PV array of claim 1, wherein the design strength of the array is capable of withstanding at least 60 pounds per square foot of wind load and gusts to 130 mph.

13. The PV array of claim 1, wherein the design strength of the array is capable of withstanding at least 60 pounds per square foot of dead load.

14. The PV array of claim 1, wherein each solar panel laminate is capable of generating at least 100 W at STC(Pm).

15. The PV array of claim 1, wherein the PV array is capable of generating at least 500 W.

16. The PV array of claim 1, wherein the PV array is capable of generating at least 20 kW.

17. The PV array of claim 6, wherein at least some of the crossmembers are electrically conductive.

18. The PV array of claim 6, wherein at least one grounding means is the crossmembers.

19. The PV array of claim 6, wherein the grounding means is not the crossmembers.

20. The PV array of claim 1, wherein the solar cells are made from cadmium telluride, copper indium, selenide/sulfide or gallium arsenide.

21. The PV array of claim 1, wherein the solar cells are made from silicon.

22. The PV array of claim 22, wherein the silicon is crystalline or amorphous silicon.

23. The PV array of claim 1, wherein each solar panel laminate is covered with a transparent material.

24. The PV array of claim 23, wherein the transparent material is glass.

25. The PV array of claim 1, wherein each solar panel laminate comprises at least 10 solar cells.

26. The PV array of claim 1, comprising at least 2 solar panel laminates.

27. The PV array of claim 1, wherein rain cannot pass through the PV array.

28. The PV array of claim 1, wherein light cannot pass through the PV array.

29. The PV array of claim 1, wherein the solar panel laminates are electrically coupled through the electrical connectors on the laminates or a surface in proximity to the laminates, wherein the electrical connectors are leads from a junction box.

30. The PV array of claim 1, wherein the electrical connector of each solar panel laminate protrudes from an edge of each laminate or a frame circumscribing each laminate, such that the electrical connector of each laminate can be plugged into the electrical connector of an adjacent laminate by pressing the electrical connectors together.

31. The PV array of claim 30, wherein the electrical connectors are coupled by pressing the laminates together.

32. A solar panel laminate comprising
a plurality of electrically coupled solar cells;
a grounding means;
an insulating cover and backing; and
an electrical connector,
wherein the solar panel laminate can be electrically coupled to an adjacent laminate through an electrical connector disposed on, in or adjacent to the laminate or a frame circumscribing the laminate, such that the electrical connector of the laminate can be coupled to an electrical connector of the adjacent laminate by pressing the electrical connectors together or installing them in close proximity to one another.

33-124. (canceled)
